(19) United States
(12) Patent Application Publication
(10) Pub. No.: US 2024/0219654 A1
(43) Pub. Date: Jul. 4, 2024

(54) OPTICAL SEMICONDUCTOR PACKAGE AND METHOD

(71) Applicant: Intel Corporation, Santa Clara, CA (US)

(72) Inventors: Ziyin Lin, Chandler, AZ (US); Yiqun Bai, Chandler, AZ (US); Bohan Shan, Chandler, AZ (US); Kyle Jordan Arrington, Gilbert, AZ (US); Haobo Chen, Chandler, AZ (US); Dingying Xu, Chandler, AZ (US); Robert Alan May, Chandler, AZ (US); Gang Duan, Chandler, AZ (US); Bai Nie, Chandler, AZ (US); Srinivas Venkata Ramanuja Pietambaram, Chandler, AZ (US)

(73) Assignee: Intel Corporation, Santa Clara, CA (US)

(21) Appl. No.: 18/089,892

(22) Filed: Dec. 28, 2022

(51) Int. Cl. G02B 6/42; H01L 25/16

(52) U.S. Cl. CPC G02B 6/4214; H01L 25/167

(57) ABSTRACT

A semiconductor device and associated methods are disclosed. In one example, the electronic device includes a photonic die and a glass substrate. In selected examples, the semiconductor device includes one or more turning mirrors to direct an optical signal between the photonic die and the glass substrate. Configurations of turning mirrors are provided to improve signal integrity and manufacturability.

### TECHNICAL FIELD

Example devices and methods described herein generally relate to semiconductor devices. In one example, devices and methods described include one or more photonic devices.

### BACKGROUND

Semiconductor devices that include one or more photonic dies are described. When a photonic die is attached to a substrate, transmitting and receiving an optical signal between a photonic die and external components is necessary. One or more turning mirrors are often used to route optical signals. Fabricating and aligning turning mirrors can be difficult. It is desired to have device components, arrangements and methods that address these concerns, and other technical challenges.

### BRIEF DESCRIPTION OF THE DRAWINGS

FIG. 1 shows a semiconductor device in accordance with some example embodiments.

FIG. 2 shows portion of a photonic die and a turning mirror in accordance with some example embodiments.

FIG. 3A-3C show different configurations of a photonic die and a turning mirror in accordance with some example embodiments.

FIG. 4A-4C show different configurations of an interface between a photonic die and a substrate in accordance with some example embodiments.

FIG. 5A-5C show different configurations of turning mirror components in accordance with some example embodiments.

FIG. 6 shows another semiconductor device in accordance with some example embodiments.

FIG. 7 shows a turning mirror assembly in accordance with some example embodiments.

FIG. 8A-8E show selected stages of manufacture of a turning mirror assembly in accordance with some example embodiments.

FIG. 9 shows another semiconductor device in accordance with some example embodiments.

FIG. 10A-10F show selected stages of manufacture of a semiconductor device in accordance with some example embodiments.

FIG. 11 shows a system that may incorporate semiconductor devices and methods, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

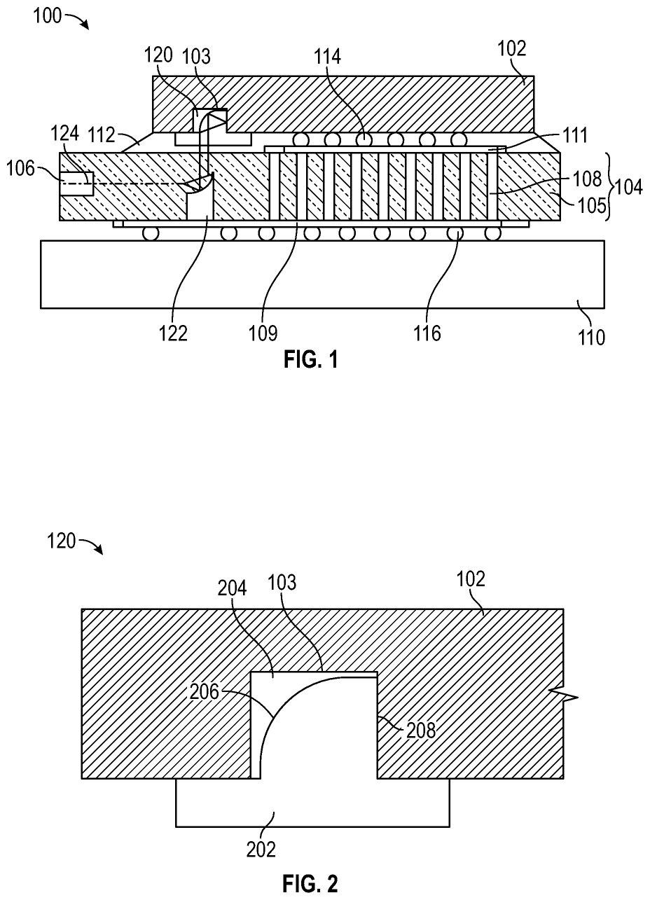

FIG. 1 shows a semiconductor device 100 according to one example. A photonic die 102 is shown coupled to a glass substrate 104. In the example shown, the glass substrate 104 is further coupled to a circuit board 110. In one example, the circuit board 110 includes a mother board, although the invention is not so limited.

Optical signals, in the form of a beam 124, are sent and received by the photonic die. In the example of FIG. 1, a first turning mirror assembly 120 and a second turning mirror assembly 122 are used to direct the beam 124 from the photonic die 102 to an external component. In one example, a port 106 is included for connection to an external component, or a waveguide such as a fiber optic line (not shown).

The photonic die 102 is shown coupled to the glass substrate 104 through first bump connections 114. In one example the first bump connections 114 include solder. The glass substrate 104 is shown coupled to the circuit board 110 through second bump connections 116. In one example the second bump connections 116 include solder. The glass substrate 104 may include a silicate-based glass (e.g., lithium-silicate, borosilicate, aluminum silicate, etc.). In variations, the glass of the glass substrate 104 is a lower quality glass (e.g., glass made with soda lime), or a higher quality glass (e.g., quartz glass made with fused silica). In the example shown, one or more die side layers 111 and one or more land side layers 109 are coupled to opposing major surfaces of the glass substrate 104. One or more through glass vias are shown passing between the opposing major surfaces of the glass substrate 104. In the example shown, the through glass vias are filled with a metallic conductor 108 such as copper. The layers 111, 109 may be used to redistribute electrical pathways between the photonic die 102 and the circuit board 110.

The optical pathway between the photonic die 102 and the port 106 may include a number of interfaces between components. It is desirable to minimize any signal disruption that might be induced at an interface. In one example, an underfill 112 is included between the photonic die 102 and the glass substrate 104. In one example, the underfill 112 includes optically transparent underfill. Other properties such as index of refraction of the underfill 112 may be considered. In one example an index of refraction of the underfill 112 substantially matches an index of refraction of the glass substrate 104.

FIG. 2 shows a close up cross section of the first turning mirror 120. In FIG. 2, a cavity 103 is shown within the photonic die 102 that encloses all or a portion of the first turning mirror 120. The first turning mirror 120 includes a glass turning mirror base 202 and a polymer fill 204. In one example a reflective coating is included over the glass turning mirror base 202 at an interface 206 between the glass turning mirror base 202 and the polymer fill 204. In one example the reflective coating includes titanium and aluminum, although the invention is not so limited.

A beam interface 208 is shown between the photonic die 102 and the glass turning mirror base 202 of the first turning mirror 120. In one example, the beam interface 208 is a direct interface between the photonic die 102 and the glass turning mirror base 202. In other words, there are no intervening layers or adhesives between the photonic die 102 and the glass turning mirror base 202. By eliminating an intervening layer, index of refraction issues are eliminated, and a lower noise, higher quality beam interaction is provided at interface 208.

In one example the interface 208 includes silicon and oxygen bonding between adjacent surfaces at the direct interface. In one example, a process is used to directly attach the glass turning mirror base 202 to the exposed surface of the photonic die 102 to form the direct interface 208. In one example a solvent clean step is first performed. Solvents that may be used include, but are not limited to, H₂O, H₂O₂, NH₄OH, etc. In one example, a plasma activation is then performed. Suitable plasmas include oxygen or nitrogen plasma activation. In one example, a cleaning is performed after plasma activation with another solvent such as de-ionized water. After the plasma activation, the activated surface of the glass turning mirror base 202 is brought into contact with the photonic die 102. Due to the surface activation, direct bonding occurs. In one example the direct bonding includes silicon and oxygen bonding. In one example, a final anneal step is performed after the direct bonding. One example of an anneal process includes heating to between 300° C. and 400° C. although the invention is not so limited.

The process for forming interface 208 (cleaning, activating, annealing, etc.) may be performed on one or both surfaces of the glass turning mirror base 202 and the photonic die 102. In one example, the process is only performed on the glass turning mirror base 202.

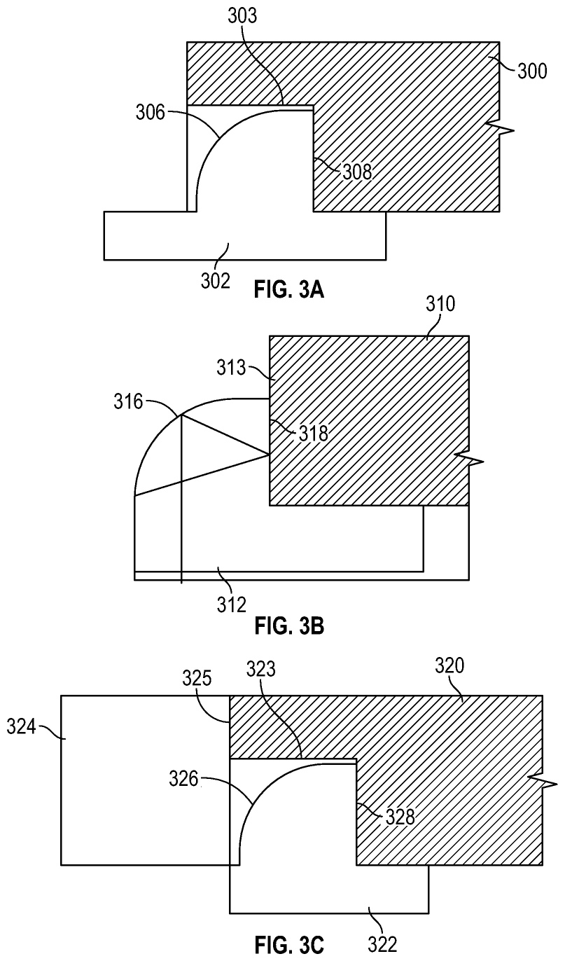

Although a direct bonded interface 208 is shown within a cavity 103, the invention is not so limited. FIG. 3A shows a glass turning mirror base 302 with a reflective coating at interface 306. The glass turning mirror base 302 forms a direct interface 308 with a photonic die 300. In the example of FIG. 3A, the direct interface 308 is within a notch 303 in an edge of the photonic die 300.

FIG. 3B shows another glass turning mirror base 312 with a reflective coating at interface 316. The glass turning mirror base 312 forms a direct interface 318 with a photonic die 310. In the example of FIG. 3B, the direct interface 318 is on an edge 313 of the photonic die 310.

FIG. 3C shows another glass turning mirror base 322 with a reflective coating at interface 326. The glass turning mirror base 322 forms a direct interface 328 with a photonic die 320. In the example of FIG. 3C, a silicon block 324 is further included adjacent to the glass turning mirror base 322. The silicon block 324 abuts a notch 323 and forms an interface 325 with the photonic die 320 and the turning mirror. In one example, a notch 323 in an edge of a die 320 may be more fragile, due to stress concentrations in corners at the edge. By including a dummy die or silicon block 324 at the interface 325, the edge is reinforced, and fractures are less likely. In one example, the silicon block 324 provides physical protection, and does not need to be in direct contact with the notch 323 at the interface 325, but only needs to be adjacent the notch 325. A small gap at the interface 325 is acceptable.

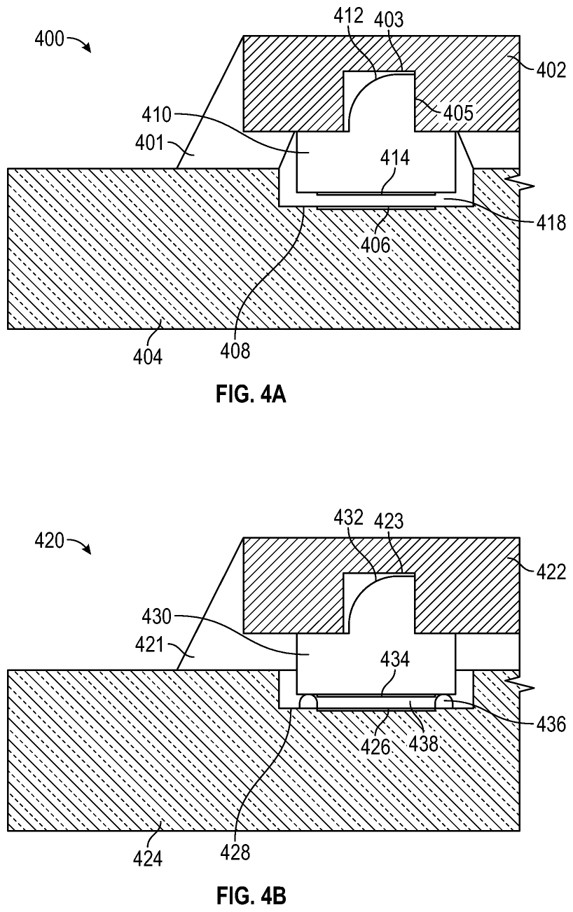

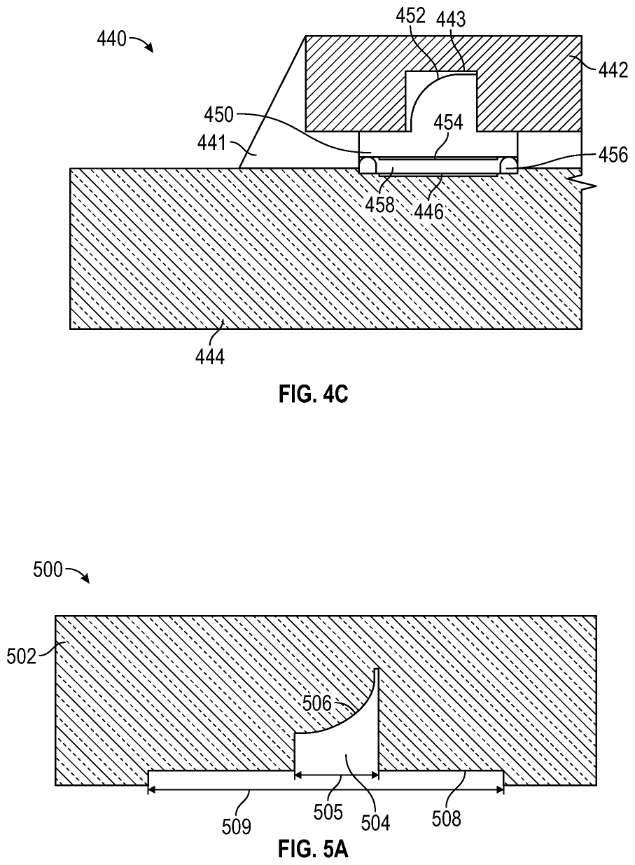

FIG. 4A shows a semiconductor device 400 according to one example. A photonic die 402 is shown coupled to a glass substrate 404. A turning mirror assembly 410 is shown between the photonic die 402 and the glass substrate 404. In one example the portion of the semiconductor device 400 is included in a higher level device, similar to semiconductor device 100 from FIG. 1.

The turning mirror assembly 410 of FIG. 4A is shown within a cavity 403 within the photonic die 402, although the invention is not so limited. The turning mirror assembly 410 includes a reflective coating is included over a glass turning mirror base at an interface 412 between the glass turning mirror base and a polymer fill. In one example the reflective coating includes titanium and aluminum, although the invention is not so limited. At the photonic die 402, an optical signal is transmitted at interface 405.

A transmitting surface 414 of the turning mirror assembly 410 is further shown, wherein the transmitting surface 414 is parallel to a corresponding surface 406 of the glass substrate 404. As discussed above, intervening layers between components in a beam path may cause noise or signal degradation. In the example of FIG. 4A, the transmitting surface 414 of the turning mirror assembly 410 is separated from the glass substrate 404 by an amount of gas filled space 418. In one example, the gas in the gas filled space 418 includes air. Other examples may include nitrogen, an inert gas, etc. By using a gas filled space, instead of a polymer, a signal quality between the transmitting surface 414 and the glass substrate 404 is improved. In one example, an anti-reflective coating is included on one or more of the transmitting surface 414 and/or corresponding surface 406 of the glass substrate 404. The anti-reflective coating may further improve signal quality when utilizing a gas filled space 418.

In the example of FIG. 4A, an underfill 401 is further included. In one example, the underfill 401 is similar to underfill 112 from FIG. 1. Underfills are useful to help adhere the photonic die 402 to the glass substrate 404. In one example, the transmitting surface 414 of the turning mirror assembly 410 is located within a cavity 408 in the glass substrate 404. The inclusion of cavity 408 channels underfill 401 around the cavity 408 during manufacture, due to surface tension effects when the underfill is applied as a liquid. The cavity 408 therefore helps maintain the gas filled space 418.

FIG. 4B shows another semiconductor device 420 according to one example. A photonic die 422 is shown coupled to a glass substrate 424. A turning mirror assembly 430 is shown between the photonic die 422 and the glass substrate 424. In one example the portion of the semiconductor device 420 is included in a higher level device, similar to semiconductor device 100 from FIG. 1.

The turning mirror assembly 430 of FIG. 4B is shown within a cavity 423 within the photonic die 422, although the invention is not so limited. The turning mirror assembly 430 includes a reflective coating is included over a glass turning mirror base at an interface 432 between the glass turning mirror base and a polymer fill. In one example the reflective coating includes titanium and aluminum, although the invention is not so limited.

A transmitting surface 434 of the turning mirror assembly 430 is further shown, wherein the transmitting surface 434 is parallel to a corresponding surface 426 of the glass substrate 424. In the example of FIG. 4B, the transmitting surface 434 of the turning mirror assembly 430 is separated from the glass substrate 424 by an amount of gas filled space 438. In one example, an anti-reflective coating is included on one or more of the transmitting surface 434 and/or corresponding surface 426 of the glass substrate 424.

In the example of FIG. 4B, an underfill 421 is further included. In one example, the transmitting surface 434 of the turning mirror assembly 430 is located within a cavity 428 in the glass substrate 424. As noted above, the inclusion of cavity 408 channels underfill 401 around the cavity 408 during manufacture, due to surface tension effects when the underfill is applied as a liquid. The cavity 408 therefore helps maintain the gas filled space 418. In the example of FIG. 4B, a polymeric seal 436 is further included around a periphery of the transmitting surface 434, between the transmitting surface 434 and the corresponding surface 426 of the glass substrate 424. The inclusion of the polymeric seal 436 further ensures that underfill 421 does not intrude into the gas filled space 438. In one example, the polymeric seal 436 includes silicone. In one example, the polymeric seal 436 includes polyurethane.

FIG. 4C shows another semiconductor device 440 according to one example. A photonic die 442 is shown coupled to a glass substrate 444. A turning mirror assembly 450 is shown between the photonic die 442 and the glass substrate 444. In one example the portion of the semiconductor device 440 is included in a higher level device, similar to semiconductor device 100 from FIG. 1.

The turning mirror assembly 450 of FIG. 4C is shown within a cavity 443 within the photonic die 442, although the invention is not so limited. The turning mirror assembly 450 includes a reflective coating is included over a glass turning mirror base at an interface 452 between the glass turning mirror base and a polymer fill. In one example the reflective coating includes titanium and aluminum, although the invention is not so limited.

A transmitting surface 454 of the turning mirror assembly 450 is further shown, wherein the transmitting surface 454 is parallel to a corresponding surface 446 of the glass substrate 444. In the example of FIG. 4C, the transmitting surface 454 of the turning mirror assembly 450 is separated from the glass substrate 444 by an amount of gas filled space 458. In one example, an anti-reflective coating is included on one or more of the transmitting surface 454 and/or corresponding surface 446 of the glass substrate 444. In the example of FIG. 4C, an underfill 441 is further included.

In the example of FIG. 4C, a polymeric seal 456 is included around a periphery of the transmitting surface 454, between the transmitting surface 454 and the corresponding surface 446 of the glass substrate 444. The inclusion of the polymeric seal 456 ensures that underfill 441 does not intrude into the gas filled space 458. In the example of FIG. 4C, there is no cavity adjacent to the transmitting surface 454 in the glass substrate 444. The corresponding surface 446 of the glass substrate 444 is coplanar with the rest of the glass substrate 444. In the example of FIG. 4C, the inclusion of the polymeric seal 456 ensures that underfill 441 does not intrude into the gas filled space 458.

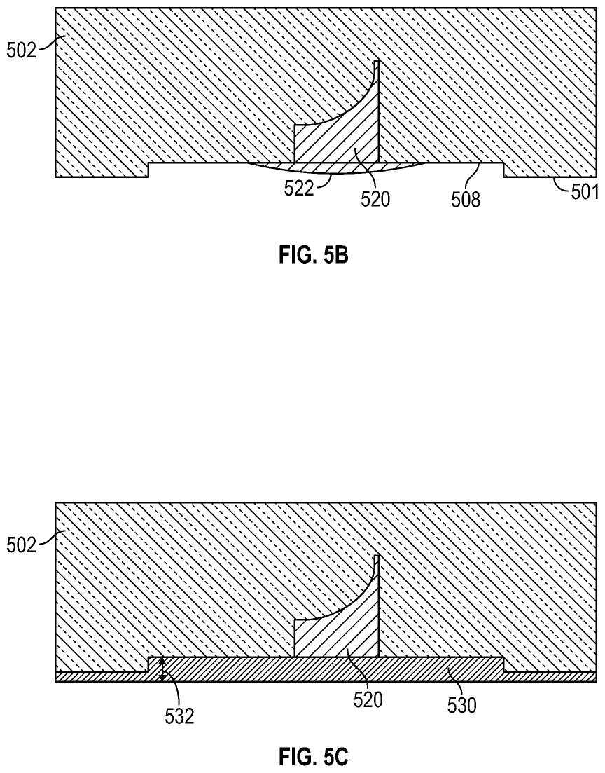

FIG. 5A shows a glass substrate 502 that may be used with a photonic die in any semiconductor device as shown in the present disclosure. FIGS. 5A-5C show selected stages in manufacture of a turning mirror. In FIG. 5A, a first cavity 504 is formed in the glass substrate 502. The first cavity 504 has a first footprint 505. A mirror is formed on a surface 506 within the first cavity 504. Examples of coatings to form the mirror include, but are not limited to, titanium and aluminum. A second cavity 508 is formed in the glass substrate 502. The second cavity 508 has a second footprint 509 that encompasses the first footprint 505. Although in FIG. 5A, the second cavity 508 is centered about the first cavity 504, the invention is not so limited. In other examples, the second cavity 508 is offset to one side of the first cavity 504.

FIG. 5B shows a first polymer fill material 520 within the first cavity 504. In one example, the first polymer fill material 520 includes epoxy. In one example, the first polymer fill material 520 includes polyurethane. In the example of FIG. 5B, the first polymer fill material overfills the first cavity and occupies a portion of the second cavity as indicated by overfill amount 522. In manufacture, accurately dispensing polymer fill material can be difficult. An overfill amount may be difficult to remove, and require expensive processing such as grinding or polishing. Underfilling the first cavity 504 may lead to cracking and cause an unwanted reduction in manufacturing yield. In the examples of FIGS. 5A-5C the inclusion of the second cavity 508 overcomes these challenges.

In one example, the dispensing of the first polymer fill material 520 may be adjusted to either fill the first cavity 504 flush, or overfill the first cavity 504. Even with limited process control, this eliminates the possibility that the first cavity 504 will be underfilled, and results in a worst case scenario of the overfill amount 522 shown in FIG. 5B.

Because the second cavity 508 is included, the overfill amount 522 is still within a bottom surface 501 of the glass substrate 502, and does not require any grinding or chemical mechanical polishing. FIG. 5C further shows a second polymer fill material 530 within the second cavity 508. Because the second cavity 508 is wider than the first cavity, an amount of overfilling or underfilling of the second cavity 508 does not result in as large a difference in Z-height 532 of the second polymer fill material 530. As a result, the second polymer fill material 530 may not require any grinding or polishing.

In one example, the second polymer fill material 530 is different from the first polymer fill material 520. In one example, the second polymer fill material 530 is easier to remove/adjust as compared to the first polymer fill material 520. In the event that the Z-height 532 of the second polymer fill material 530 does need adjusting, the chosen second polymer fill material 530 may be selected for easier adjustment, such as easier griding. In one example the second polymer fill material 530 includes Ajinomoto Build-up Film (ABF). In one example the second polymer fill material 530 includes a photo-imageable dielectric.

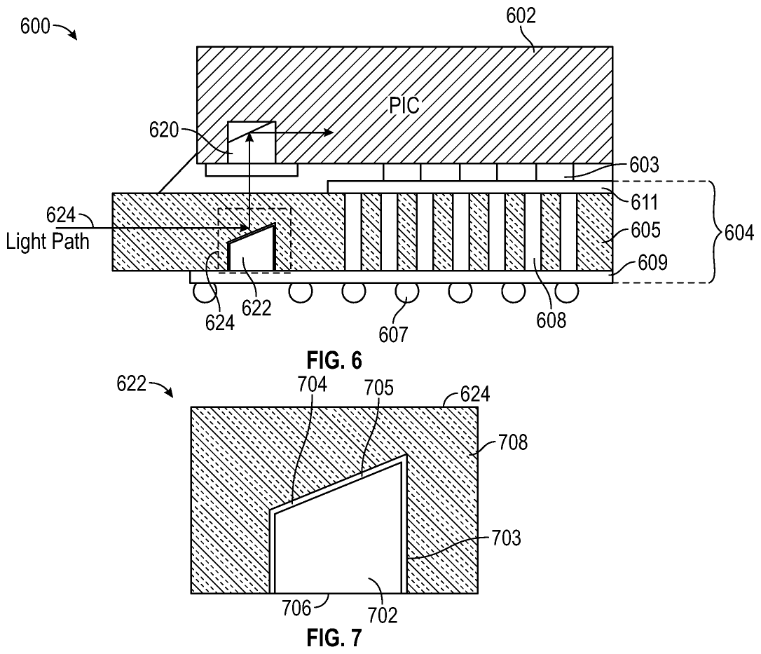

FIG. 6 shows a semiconductor device 600 according to one example. A photonic die 602 is shown coupled to a glass substrate 604. Optical signals, in the form of a beam 624, are sent and received by the photonic die. In the example of FIG. 6, a first turning mirror assembly 620 and a second turning mirror assembly 622 are used to direct the beam 624 from the photonic die 602 to an external component.

The photonic die 602 is shown coupled to the glass substrate 604 through first bump connections 603. In one example the first bump connections 603 include solder. The glass substrate 104 may include a silicate-based glass (e.g., lithium-silicate, borosilicate, aluminum silicate, etc.). In variations, the glass of the glass substrate 104 is a lower quality glass (e.g., glass made with soda lime), or a higher quality glass (e.g., quartz glass made with fused silica). In the example shown, one or more die side layers 611 and one or more land side layers 609 are coupled to opposing major surfaces of the glass substrate 604. The die side layer 611 and land side layer 609 may be the same material, or they may be formed from different materials. In one example, both the die side layers and the land side layers 609 are laminated in one operation, therefore having the layers 611, 609 formed from the same material is advantageous. One or more through glass vias are shown passing between the opposing major surfaces of the glass substrate 604. In the example shown, the through glass vias are filled with a metallic conductor 608 such as copper. The layers 611, 609 may be used to redistribute electrical pathways between the photonic die 602, through the glass substrate 604 and to additional components such as a mother board (not shown). Solder connections 607 may be used to connect to a mother board.

In the Example of FIG. 6, the second turning mirror 622 is fabricated separately and later secured within the glass substrate 604. Fabricating the second turning mirror 622 separately and later coupling to the glass substrate 604 may be easier and more reliable than fabricating the second mirror within the glass substrate 604. A border 624 of a separately fabricated second turning mirror assembly 622 is shown in FIGS. 6 and 7.

FIG. 7 shows a second turning mirror assembly 622, including a mirror base 702, and a mirror coating 705 on a top 704 and side surfaces 703 of the mirror base 702. An encapsulant 708 is further shown over the mirror coating 705 and the mirror base 702.

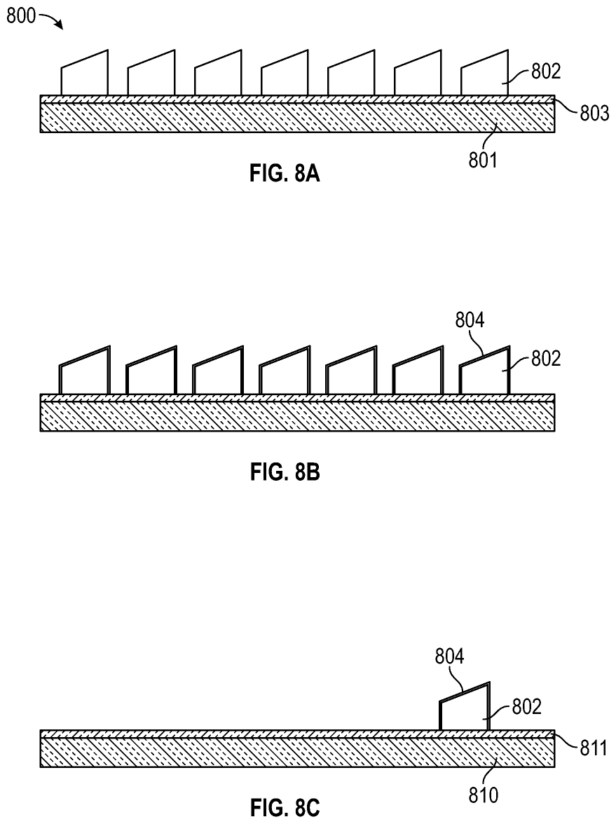

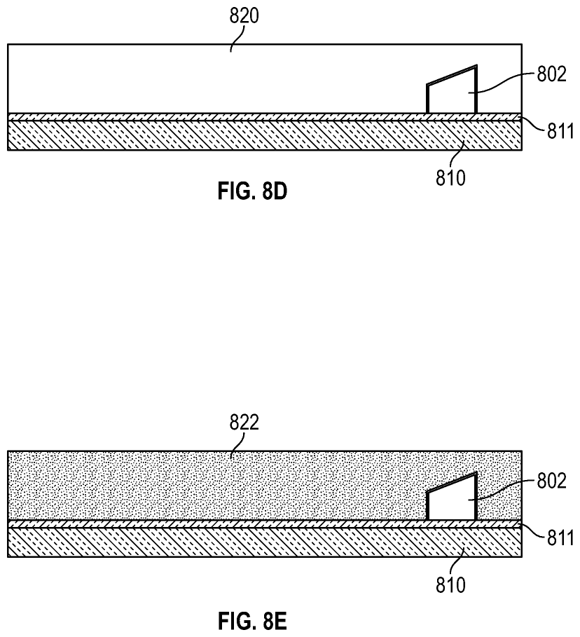

FIGS. 8A-8E show selected stages of manufacture of a turning mirror assembly. In FIG. 8A, a number of pre-formed mirror bases 802 are placed on a carrier 801. Preforming the mirror bases 802 allows increased consistency and the ability to easily manufacture more complex geometries for the mirror bases 802. An adhesive 803 is shown securing the pre-formed mirror bases 802 to the carrier 803.

In FIG. 8B, a top and side surfaces of the mirror bases are coated with a reflective material 804 while attached to the carrier 803 to form coated mirror bases. As in examples above, one example of a reflective coating 804 includes titanium and aluminum. In one example, sputtering is used to form the reflective coating 804, although the invention is not so limited.

As shown in FIG. 8B, a top surface of the carrier 801 and the adhesive 803 are also coated with the reflective material 804. In FIG. 8C, the coated mirror bases 802 are removed from the carrier 801, and attached to a second carrier 810 using a second adhesive 811. Because the coated mirror bases 802 were attached to the carrier 801 during coating, no reflective coating 804 is included on a bottom surface of any of the coated mirror bases 802.

In FIG. 8D, an encapsulant 820 is formed over the mirror coating 804 and the mirror base 802. FIG. 8E shows another example, where an encapsulant 822 is used that includes one or more filler materials. Filler materials may be included to modify optical or physical properties of the turning mirror assembly. In one example, the encapsulant 820 includes spin-on-glass (SOG). In selected examples, spin-on-glass material includes similar optical properties to the glass substrate 604, helping to improve signal quality.

In one example, the mirror bases 802 are formed from a material with a similar coefficient of thermal expansion to the glass substrate 604. In one example, the mirror bases 802 are formed from glass. In one example, the mirror bases 802 are formed from silicon. By forming the mirror bases 802 first, it is easier to use materials with similar coefficient of thermal expansion to the glass substrate 604. In contrast, filling a cavity in a glass substrate 604 with a material that has a coefficient of thermal expansion similar to a glass substrate can be difficult. Such materials may not flow into a cavity easily. Having materials with similar coefficients of thermal expansion may reduce or eliminated cracking during thermal cycling.

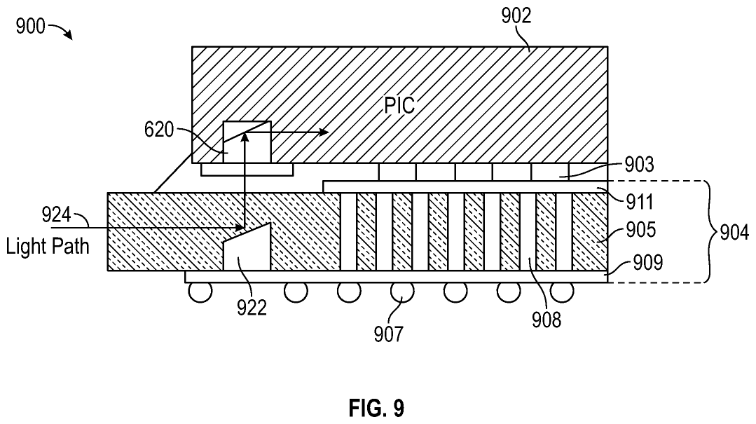

FIG. 9 shows a semiconductor device 900 according to one example. A photonic die 902 is shown coupled to a glass substrate 904. Optical signals, in the form of a beam 924, are sent and received by the photonic die. In the example of FIG. 9, a first turning mirror assembly 920 and a second turning mirror assembly 922 are used to direct the beam 924 from the photonic die 902 to an external component.

The photonic die 902 is shown coupled to the glass substrate 904 through first bump connections 903. In one example the first bump connections 903 include solder. The glass substrate 904 may include a silicate-based glass (e.g., lithium-silicate, borosilicate, aluminum silicate, etc.). In variations, the glass of the glass substrate 904 is a lower quality glass (e.g., glass made with soda lime), or a higher quality glass (e.g., quartz glass made with fused silica). In the example shown, one or more die side layers 911 and one or more land side layers 909 are coupled to opposing major surfaces of the glass substrate 904. The die side layer 911 and land side layer 909 may be the same material, or they may be formed from different materials. In one example, both the die side layers 911 and the land side layers 909 are laminated in one operation, therefore having the layers 611, 609 formed from the same material is advantageous. One or more through glass vias are shown passing between the opposing major surfaces of the glass substrate 904. In the example shown, the through glass vias are filled with a metallic conductor 908 such as copper. The layers 911, 909 may be used to redistribute electrical pathways between the photonic die 902, through the glass substrate 904 and to additional components such as a mother board (not shown). Solder connections 907 may be used to connect to a mother board.

In the example of FIG. 9, the second turning mirror assembly 922 includes a cavity in the glass substrate 904. A reflective coating is formed on a top surface of the cavity to form the mirror, and redirect the beam 924. In the example of FIG. 9, the land side layers 909 form a cover that encloses an amount of gas within the cavity in the in the glass substrate 904. By using an amount of gas within the cavity, thermal expansion issues that may be associated with a mirror base are eliminated.

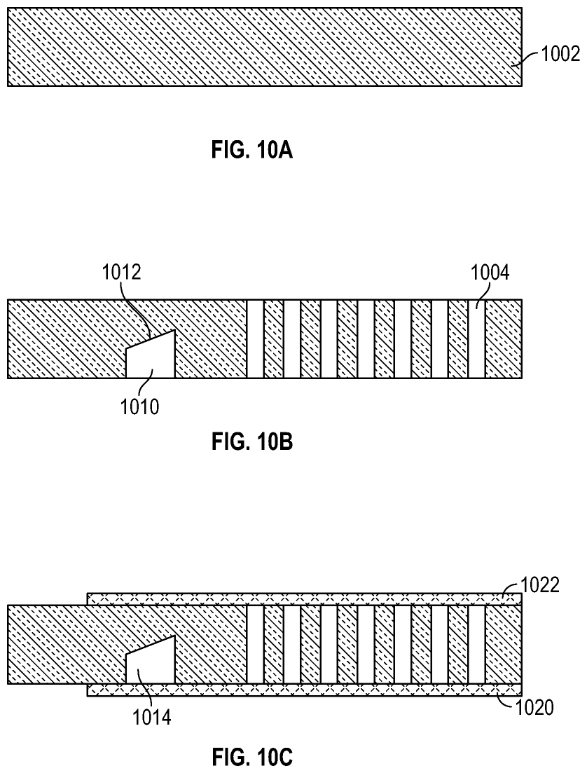

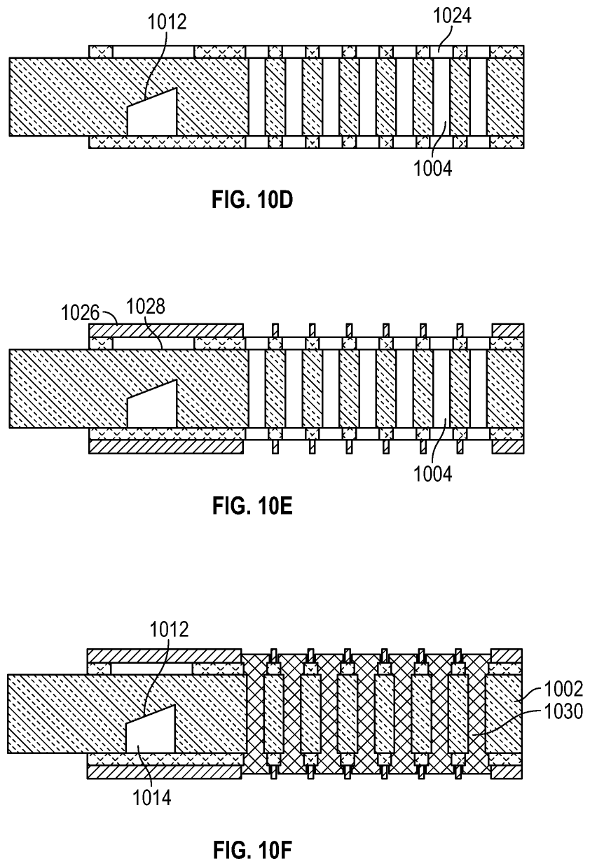

FIGS. 10A-10F show selected stages of manufacture of a semiconductor device with a second turning mirror including an amount of gas in a cavity. In FIG. 10A, a glass substrate 1002 is provided as a starting material. In FIG. 10B, a turning mirror cavity 1010 is formed within the glass substrate 1002, and a number of through glass vias 1004. A mirror is formed on a surface 1012 within the cavity 1010. As described in other examples, a reflective coating, such as metallic titanium or aluminum or alloys thereof may be used to form the mirror.

In FIG. 10C, a top dielectric layer 1022 and a bottom dielectric layer 1020 are formed over the glass substrate 1002. In one example, the top and bottom dielectric layers 1020, 1022 are formed by laminating the glass substrate 1002 with a photo imageable dielectric layer. The lamination process is capable of bridging over cavity 1010, and the cavities formed by the through glass vias 1004. By using photo imageable dielectric, subsequent operations of dielectric removal are facilitated. Photo imaging and material removal is very precise and easy to use with existing manufacturing equipment.

In FIG. 10D, the photo imageable dielectric layers 1020 and 1022 are patterned and selectively removed to expose the through glass vias 1004, while still enclosing the mirror formed within the cavity 1010.

In FIG. 10E, a second pattern layer 1026 is formed over the dielectric layers 1020, 1022. In one example, second pattern layer 1026 is formed by laminating the glass substrate 1002 with a dry film resist layer. The dry film resist layer is also patternable, and in FIG. 10E, the through glass vias 1004 are again exposed while still enclosing the mirror formed within the cavity 1010, and also protecting an optical surface 1028 where the signal beam will enter to reflect off the mirror 1012.

In FIG. 10F, the through glass vias 1004 are filled with a metallic conductor to form through glass electrical pathways. In one example, copper is plated within the through glass vias 1004 to form electrical pathways 1030. The second pattern layer 1026 is later removed to expose the optical surface 1028 over the mirror 1012. The mirror 1012 remains within the cavity 1010 that is enclosed with an amount of gas. Examples of gas include, but are not limited to, air, nitrogen, or other inert gasses.

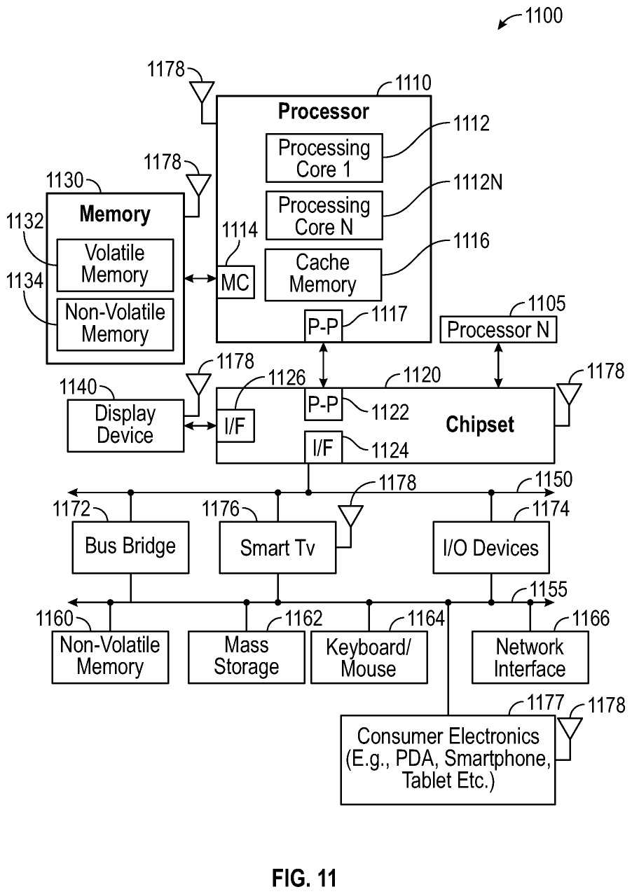

FIG. 11 illustrates a system level diagram, depicting an example of an electronic device (e.g., system) that may include a photonic die and glass substrate and/or methods described above. In one embodiment, system 1100 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 1100 includes a system on a chip (SOC) system.

In one embodiment, processor 1110 has one or more processor cores 1112 and 1112N, where 1112N represents the Nth processor core inside processor 1110 where N is a positive integer. In one embodiment, system 1100 includes multiple processors including 1110 and 1105, where processor 1105 has logic similar or identical to the logic of processor 1110. In some embodiments, processing core 1112 includes, but is not limited to, pre-fetch logic to fetch instructions, decode logic to decode the instructions, execution logic to execute instructions and the like. In some embodiments, processor 1110 has a cache memory 1116 to cache instructions and/or data for system 1100. Cache memory 1116 may be organized into a hierarchal structure including one or more levels of cache memory.

In some embodiments, processor 1110 includes a memory controller 1114, which is operable to perform functions that enable the processor 1110 to access and communicate with memory 1130 that includes a volatile memory 1132 and/or a non-volatile memory 1134. In some embodiments, processor 1110 is coupled with memory 1130 and chipset 1120. Processor 1110 may also be coupled to a wireless antenna 1178 to communicate with any device configured to transmit and/or receive wireless signals. In one embodiment, an interface for wireless antenna 1178 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 1132 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 1134 includes, but is not limited to, flash memory, phase change memory (PCM), read-only memory (ROM), electrically erasable programmable read-only memory (EEPROM), or any other type of non-volatile memory device.

Memory 1130 stores information and instructions to be executed by processor 1110. In one embodiment, memory 1130 may also store temporary variables or other intermediate information while processor 1110 is executing instructions. In the illustrated embodiment, chipset 1120 connects with processor 1110 via Point-to-Point (PtP or P-P) interfaces 1117 and 1122. Chipset 1120 enables processor 1110 to connect to other elements in system 1100. In some embodiments of the example system, interfaces 1117 and 1122 operate in accordance with a PtP communication protocol such as the Intel® QuickPath Interconnect (QPI) or the like. In other embodiments, a different interconnect may be used.

In some embodiments, chipset 1120 is operable to communicate with processor 1110, 1105N, display device 1140, and other devices, including a bus bridge 1172, a smart TV 1176, I/O devices 1174, nonvolatile memory 1160, a storage medium (such as one or more mass storage devices) 1162, a keyboard/mouse 1164, a network interface 1166, and various forms of consumer electronics 1177 (such as a PDA, smart phone, tablet etc.), etc. In one embodiment, chipset 1120 couples with these devices through an interface 1124. Chipset 1120 may also be coupled to a wireless antenna 1178 to communicate with any device configured to transmit and/or receive wireless signals. In one example, any combination of components in a chipset may be separated by a continuous flexible shield as described in the present disclosure.

Chipset 1120 connects to display device 1140 via interface 1126. Display 1140 may be, for example, a liquid crystal display (LCD), a light emitting diode (LED) array, an organic light emitting diode (OLED) array, or any other form of visual display device. In some embodiments of the example system, processor 1110 and chipset 1120 are merged into a single SOC. In addition, chipset 1120 connects to one or more buses 1150 and 1155 that interconnect various system elements, such as I/O devices 1174, nonvolatile memory 1160, storage medium 1162, a keyboard/mouse 1164, and network interface 1166. Buses 1150 and 1155 may be interconnected together via a bus bridge 1172.

In one embodiment, mass storage device 1162 includes, but is not limited to, a solid state drive, a hard disk drive, a universal serial bus flash memory drive, or any other form of computer data storage medium. In one embodiment, network interface 1166 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 11 are depicted as separate blocks within the system 1100, the functions performed by some of these blocks may be integrated within a single semiconductor circuit or may be implemented using two or more separate integrated circuits. For example, although cache memory 1116 is depicted as a separate block within processor 1110, cache memory 1116 (or selected aspects of 1116) can be incorporated into processor core 1112.

To better illustrate the method and apparatuses disclosed herein, a non-limiting list of embodiments is provided here:

Example 1 includes a semiconductor device. The device includes a photonic die coupled to a glass substrate, and a turning mirror assembly coupled between the photonic die and the glass substrate, the turning mirror assembly including a mirror on a glass turning mirror base, wherein a surface of the glass turning mirror base forms a direct interface with the photonic die.

Example 2 includes the semiconductor device of example 1, wherein the direct interface includes silicon and oxygen bonding between adjacent surfaces at the direct interface.

Example 3 includes the semiconductor device of any one of examples 1-2, wherein the direct interface is within a cavity in the photonic die.

Example 4 includes the semiconductor device of any one of examples 1-3, wherein the direct interface is on an edge of the photonic die.

Example 5 includes the semiconductor device of any one of examples 1-4, wherein the direct interface is within a notch in an edge of the photonic die.

Example 6 includes the semiconductor device of any one of examples 1-5, further including a silicon block that abuts the notch and the turning mirror assembly.

Example 7 includes a computing system. The system includes an electronic die coupled to a glass substrate, a photonic die coupled to the glass substrate and in communication with the electronic die; and a first turning mirror assembly coupled to the photonic die, the first turning mirror assembly including a mirror on a glass turning mirror base, wherein a surface of the glass turning mirror base forms a direct interface with the photonic die. The system also includes a second turning mirror assembly located within the glass substrate, and an optical fiber positioned to receive optical signals from the second turning mirror.

Example 8 includes the computing system of example 7, wherein the turning mirror base includes fused silica.

Example 9 includes the computing system of any one of examples 7-8, wherein the direct interface includes silicon and oxygen bonding between adjacent surfaces at the direct interface.

Example 10 includes the computing system of any one of examples 7-9, wherein the direct interface is within a cavity in the photonic die.

Example 11 includes the computing system of any one of examples 7-10, wherein the direct interface is on an edge of the photonic die.

Example 12 includes the computing system of any one of examples 7-11, wherein the direct interface is within a notch in an edge of the photonic die.

Example 13 includes the computing system of any one of examples 7-12, further including a silicon block that abuts the notch and the turning mirror assembly.

Example 14 includes the computing system of any one of examples 7-13, further including an antenna coupled to the electronic die.

Example 15 includes the computing system of any one of examples 7-14, further including an end user display device coupled to the electronic die.

Example 16 includes a method of forming a semiconductor device. The method includes forming an optical signal interface surface on a photonic die, forming a turning mirror assembly, including a reflective coating on a glass mirror base, activating a surface of the glass mirror base, and forming a direct interface between the activated surface of the mirror base and the optical signal interface surface.

Example 17 includes the method of example 16, wherein activating a surface of the glass mirror base includes plasma activation.

Example 18 includes the method of any one of examples 16-17, wherein activating a surface of the glass mirror base includes a solvent clean prior to plasma activation.

Example 19 includes the method of any one of examples 16-18, wherein activating a surface of the glass mirror base includes cleaning with de-ionized water after the plasma activation.

Example 20 includes the method of any one of examples 16-19, wherein forming a direct interface includes annealing the interface while the glass mirror base is in contact with the optical signal interface surface.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. A semiconductor device, comprising:
a photonic die coupled to a glass substrate;
a turning mirror assembly coupled between the photonic die and the glass substrate, the turning mirror assembly including a mirror on a glass turning mirror base; and
wherein a surface of the glass turning mirror base forms a direct interface with the photonic die.

2. The semiconductor device of claim 1, wherein the direct interface includes silicon and oxygen bonding between adjacent surfaces at the direct interface.

3. The semiconductor device of claim 1, wherein the direct interface is within a cavity in the photonic die.

4. The semiconductor device of claim 1, wherein the direct interface is on an edge of the photonic die.

5. The semiconductor device of claim 1, wherein the direct interface is within a notch in an edge of the photonic die.

6. The semiconductor device of claim 1, further including a silicon block that abuts the notch and the turning mirror assembly.

7. A computing system, comprising:
an electronic die coupled to a glass substrate;
a photonic die coupled to the glass substrate and in communication with the electronic die;
a first turning mirror assembly coupled to the photonic die, the first turning mirror assembly including a mirror on a glass turning mirror base; and
wherein a surface of the glass turning mirror base forms a direct interface with the photonic die;
a second turning mirror assembly located within the glass substrate; and
an optical fiber positioned to receive optical signals from the second turning mirror.

8. The computing system of claim 7, wherein the turning mirror base includes fused silica.

9. The computing system of claim 7, wherein the direct interface includes silicon and oxygen bonding between adjacent surfaces at the direct interface.

10. The computing system of claim 7, wherein the direct interface is within a cavity in the photonic die.

11. The computing system of claim 7, wherein the direct interface is on an edge of the photonic die.

12. The computing system of claim 7, wherein the direct interface is within a notch in an edge of the photonic die.

13. The computing system of claim 7, further including a silicon block that abuts the notch and the turning mirror assembly.

14. The computing system of claim 7, further including an antenna coupled to the electronic die.

15. The computing system of claim 14, further including an end user display device coupled to the electronic die.

16. A method of forming a semiconductor device, comprising:
forming an optical signal interface surface on a photonic die;
forming a turning mirror assembly, including a reflective coating on a glass mirror base;
activating a surface of the glass mirror base; and
forming a direct interface between the activated surface of the mirror base and the optical signal interface surface.

17. The method of claim 16, wherein activating a surface of the glass mirror base includes plasma activation.

18. The method of claim 17, wherein activating a surface of the glass mirror base includes a solvent clean prior to plasma activation.

19. The method of claim 18, wherein activating a surface of the glass mirror base includes cleaning with de-ionized water after the plasma activation.

20. The method of claim 19, wherein forming a direct interface includes annealing the interface while the glass mirror base is in contact with the optical signal interface surface.
